(19) United States
(12) Patent Application Publication
(10) Pub. No.: US 2016/0141452 A1
(43) Pub. Date: May 19, 2016

(54) LIGHTING EMITTING DEVICE, MANUFACTURING METHOD THEREOF AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei (CN)

(72) Inventor: Peng CHEN, Beijing (CN)

(21) Appl. No.: 14/802,591

(22) Filed: Jul. 17, 2015

(30) Foreign Application Priority Data
Nov. 13, 2014 (CN) 201410642075.X

(51) Int. Cl. H01L 33/18; H01L 33/36; H01L 33/14

(52) U.S. Cl. CPC H01L 33/18; H01L 33/14; H01L 33/36; H01L 2933/0025; H01L 2933/0058

(57) ABSTRACT

The present invention discloses a light emitting device, a manufacturing method thereof and a display device. The light emitting device comprises a substrate. An anode layer, a functional layer and a cathode layer are provided above the substrate, and the functional layer is provided between the anode layer and the cathode layer. A transmission enhanced layer is further provided on the substrate. The transmission enhanced layer comprises a plurality of photonic crystal microstructures, so that light is refracted while transmitting through the transmission enhanced layer, so as to form light in different directions and thus to reduce an incident angle of light incident to the substrate. Therefore, the total reflection generated when light transmits through an interface between the substrate and the air is reduced, thereby improving luminous efficiency and reducing power loss.

### FIELD OF THE INVENTION

The present invention relates to the field of display technology, and in particular to a light emitting device, a manufacturing method thereof and a display device.

### BACKGROUND OF THE INVENTION

FIG. 1 is a light path diagram of a light emitting device in the prior art. As shown in FIG. 1, the light emitting device includes a substrate 101, and a planarization layer 102, an anode layer 103, a functional layer 104 and a cathode layer 105 are successively provided on the substrate 101. The light emitting device is of a bottom light emitting structure, in which light 106 is emergent from the substrate 101. As it is likely to generate total reflection on an interface between the substrate 101 and the air, a part of light cannot be emergent from the substrate 101, so that the luminous efficiency is reduced and the power loss is increased.

### SUMMARY OF THE INVENTION

To solve the above problem, the present invention provides a light emitting device, a manufacturing method thereof and a display device, which are used for solving the problem of low luminous efficiency and high power loss of a light emitting device in the prior art.

To this end, the present invention provides a light emitting device, including a substrate, wherein an anode layer, a functional layer and a cathode layer are provided above the substrate, the functional layer being provided between the anode layer and the cathode layer, a transmission enhanced layer being further provided on the substrate, and the transmission enhanced layer comprising a plurality of photonic crystal microstructures.

Preferably, the plurality of photonic crystal microstructures are arranged at intervals.

Preferably, the plurality of photonic crystal microstructures are arranged at equal intervals.

Preferably, the transmission enhanced layer is provided under the anode layer.

Preferably, the height of each of the photonic crystal microstructures is 0.4 μm.

Preferably, the interval between every two adjacent photonic crystal microstructures of the plurality of photonic crystal microstructures is 0.6 μm.

Preferably, a cross section of each of the photonic crystal microstructures parallel to a plane of the transmission enhanced layer is a regular polygon.

Preferably, the transmission enhanced layer is made of silicon nitride or silicon oxide.

Preferably, the light emitting device further includes a planarization layer, wherein the planarization layer is provided between the transmission enhanced layer and the anode layer, and a part of the planarization layer is located within the intervals between the plurality of photonic crystal microstructures.

Preferably, each of the plurality of photonic crystal microstructures is a protrusion formed on the substrate.

The present invention further provides a display device, including any one of the above light emitting device.

The present invention further provides a method for manufacturing a light emitting device, including: forming a transmission enhanced layer on a substrate, so that the transmission enhanced layer includes a plurality of photonic crystal microstructures; and forming an anode layer, a functional layer and a cathode layer above the substrate with the transmission enhanced layer formed thereon, so that the functional layer is provided between the anode layer and the cathode layer.

The present invention has the following beneficial effects:

in the light emitting device, the manufacturing method thereof and the display device provided by the present invention, the light emitting device includes a substrate; an anode layer, a functional layer and a cathode layer are provided above the substrate, and the functional layer is provided between the anode layer and the cathode layer; a transmission enhanced layer is further provided on the substrate; the transmission enhanced layer includes a plurality of photonic crystal microstructures, so that light is refracted while transmitting through the transmission enhanced layer, so as to form light in different directions and thus to reduce an incident angle of light incident to the substrate. Therefore, the total reflection generated when light transmits through an interface between the substrate and the air is reduced, thereby improving luminous efficiency and reducing power loss.

### BRIEF DESCRIPTION OF THE DRAWINGS

FIG. 1 is a light path diagram of a light emitting device in the prior art;

FIG. 2 is a structural diagram of a light emitting device provided by a first embodiment of the present invention;

FIG. 3 is a structural diagram of a transmission enhanced layer in the light emitting device shown in FIG. 2;

FIG. 4 is a light path diagram in the light emitting device shown in FIG. 2; and

FIG. 5 is a flowchart of a method for manufacturing a light emitting device provided by a third embodiment of the present invention.

### DETAILED DESCRIPTION OF THE EMBODIMENTS

To make those skilled in the art better understand the technical solutions of the present invention, a light emitting device, a manufacturing method thereof and a display device provided by the present invention will be described below in detail with reference to the accompanying drawings.

### First Embodiment

FIG. 2 is a structural diagram of a light emitting device provided by the first embodiment of the present invention. As shown in FIG. 2, the light emitting device includes a substrate 101, and an anode layer 103, a functional layer 104 and a cathode layer 105 are successively provided on the substrate 101. A transmission enhanced layer 107 is further provided on the substrate 101. The transmission enhanced layer 107 includes a plurality of photonic crystal microstructures 108, so that light is refracted while transmitting through the transmission enhanced layer, so as to form light in different directions and thus to reduce an incident angle of light incident to the substrate 101. Therefore, the total reflection generated when light transmits through an interface between the substrate and the air is reduced, thereby improving luminous efficiency and reducing power loss.

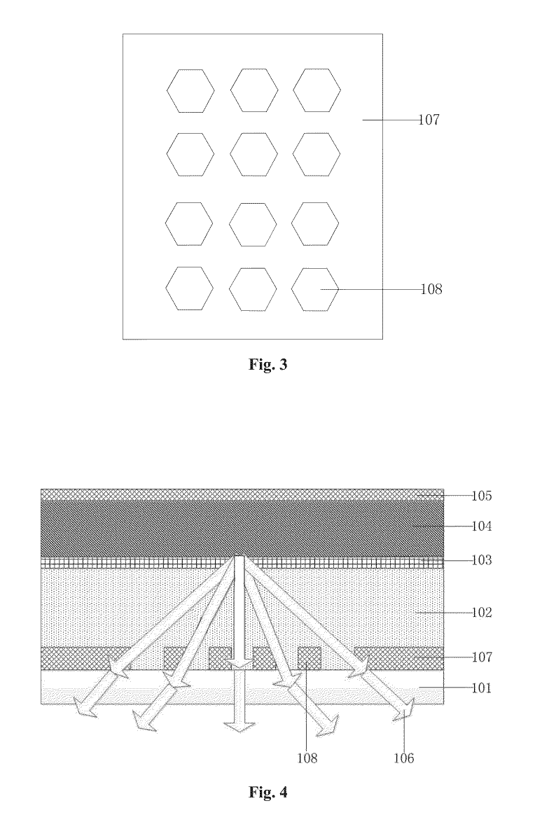

In this embodiment, the transmission enhanced layer 107 is provided under the anode layer 103. Preferably, the transmission enhanced layer 107 is made of silicon nitride or silicon oxide. Of course, the transmission enhanced layer 107 may also be made of other inorganic nonmetallic materials, and may be selected by those skilled in the art according to actual needs. In practical applications, the shapes of the plurality of photonic crystal microstructures 108 of the transmission enhanced layer 107 may differ from one another, and the plurality of photonic crystal microstructures 108 may be arranged in different ways. Preferably, the shapes of the plurality of photonic crystal microstructures 108 are identical. More preferably, the plurality of photonic crystal microstructures 108 are arranged in a regular pattern. FIG. 3 is a structural diagram of the transmission enhanced layer 107 in the light emitting device of FIG. 2. As shown in FIG. 3, a cross section of each of the photonic crystal microstructures 108 parallel to a plane of the transmission enhanced layer 107 is a regular polygon. Preferably, the regular polygon is a regular hexagon. The plurality of photonic crystal microstructures 108 are arranged at intervals. Preferably, the plurality of photonic crystal microstructures 108 are arranged at equal intervals. In other words, the plurality of photonic crystal microstructures 108 are uniformly distributed on the transmission enhanced layer 107. The interval between every two adjacent photonic crystal microstructures of the plurality of photonic crystal microstructures 108 is 0.6 μm, and the height of each of the photonic crystal microstructures 108 is 0.4 μm. In practical applications, the intervals among the plurality of photonic crystal microstructures 108 and the height of each of the photonic crystal microstructures 108 are adjustable, and may be selected by those skilled in the art according to actual needs. More preferably, a duty cycle of the plurality of photonic crystal microstructures 108 is 1:1. The duty cycle is a ratio of the total area of the cross sections of the plurality of photonic crystal microstructures 108 parallel to the plane of the transmission enhanced layer 107 to the total real of the intervals. It is to be noted that, the duty cycle of the plurality of photonic crystal microstructures 108 being 1:1 is merely a preferred embodiment, and the duty cycle of other value shall fall into the protection scope of the present invention. The same shape and corresponding regular arrangement of the plurality of photonic crystal microstructures 108 may improve the probability of refraction of light while transmitting through the transmission enhanced layer 107, thereby forming light in more different directions.

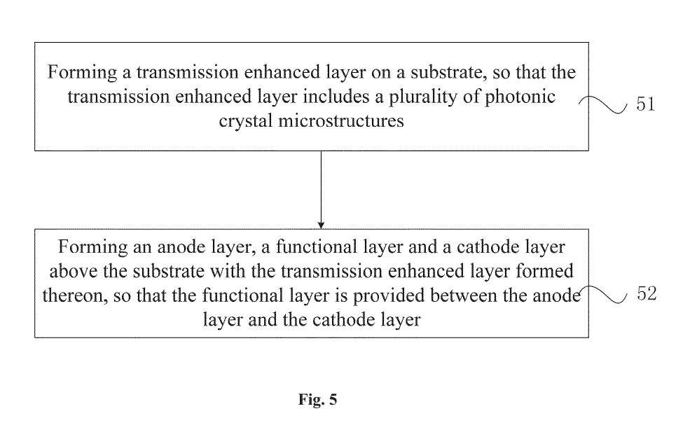

In this embodiment, the light emitting device further includes a planarization layer 102. The planarization layer 102 is provided between the transmission enhanced layer 107 and the anode layer 103, and a part of the planarization layer 102 is located within the intervals between the plurality of photonic crystal microstructures 108. Preferably, the planarization material 102 is made of RGB color filter material or PI material. FIG. 4 is a light path diagram of the light emitting device of FIG. 2. As shown in FIG. 4, the interface between the transmission enhanced layer 107 and the planarization layer 102 forms an irregular interface. Light 106 is refracted on the interface to form light at different angles, so that the incident angle of light incident to the substrate 101 is reduced. Therefore, the total reflection generated when light transmits through the interface between the substrate and the air is reduced, the luminous efficiency is improved, and the power loss is reduced.

For example, each of the plurality of photonic crystal microstructures 108 is a protrusion formed on the substrate 101.

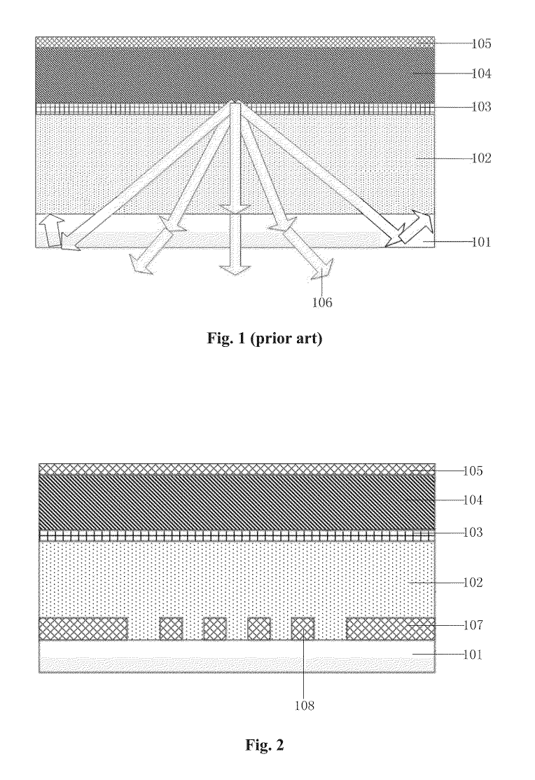

In order to make the incident angle (shown in FIG. 4) of light 106 incident to the substrate 101 after transmitting through the planarization layer 102 and the transmission enhanced layer 107 become smaller with respect to the incident angle formed in the case without the transmission enhanced layer 107 as shown in FIG. 1, those skilled in the art may determine a relationship between the refractive index of each photonic crystal microstructure 108 (e.g., each of the protrusions formed on the substrate 101) in the transmission enhanced layer 107 and the refractive index of the planarization layer 102. For example, the refractive index of each of the protrusions in the transmission enhanced layer 107 may be greater than that of the planarization layer 102.

In this embodiment, a total reflection metal layer may be provided above the cathode layer 105. The total reflection metal layer is used for totally reflecting light 106 to the transmission enhanced layer 107, and then the light is refracted by the transmission enhanced layer 107 to form light at different angles, so that the luminous efficiency is improved, and the power loss is reduced.

In the light emitting device provided by the present invention, the light emitting device includes a substrate; an anode layer, a functional layer and a cathode layer are provided above the substrate, and the functional layer is provided between the anode layer and the cathode layer; a transmission enhanced layer is further provided on the substrate; the transmission enhanced layer includes a plurality of photonic crystal microstructures, so that light is refracted while transmitting through the transmission enhanced layer, so as to form light in different directions and thus to reduce an incident angle of light incident to the substrate. Therefore, the total reflection generated when light transmits through an interface between the substrate and the air is reduced, thereby improving luminous efficiency and reducing power loss.

### Second Embodiment

This embodiment provides a display device, including the light emitting device provided by the first embodiment. For the specific structure of the light emitting device, reference may be made to the description in the first embodiment, and it will not be repeated herein.

In the display device provided by the present invention, the light emitting device includes a substrate; an anode layer, a functional layer and a cathode layer are provided above the substrate, and the functional layer is provided between the anode layer and the cathode layer; a transmission enhanced layer is further provided on the substrate; the transmission enhanced layer includes a plurality of photonic crystal microstructures, so that light is refracted while transmitting through the transmission enhanced layer, so as to form light in different directions and thus to reduce an incident angle of light incident to the substrate. Therefore, the total reflection generated when light transmits through an interface between the substrate and the air is reduced, thereby improving luminous efficiency and reducing power loss.

### Third Embodiment

FIG. 5 is a flowchart of a method for manufacturing a light emitting device provided by the third embodiment of the present invention. As shown in FIG. 5, the method for manufacturing a light emitting device includes:

Step 51: forming a transmission enhanced layer on a substrate, so that the transmission enhanced layer including a plurality of photonic crystal microstructures.

In this embodiment, the plurality of photonic crystal microstructures 108 are identical in shape and arranged in a regular pattern. Referring to FIG. 3, a cross section of each of the photonic crystal microstructures 108 parallel to a plane of the transmission enhanced layer 107 is a regular polygon. Preferably, the regular polygon is a regular hexagon. The plurality of photonic crystal microstructures 108 are arranged at intervals. Preferably, the plurality of photonic crystal microstructures 108 are arranged at equal intervals. The interval between every two adjacent photonic crystal microstructures of the plurality of photonic crystal microstructures 108 is 0.6 μm, and the height of each of the photonic crystal microstructures 108 is 0.4 μm. In practical applications, the intervals among the plurality of photonic crystal microstructures 108 and the height of each of the photonic crystal microstructures 108 are adjustable, and may be selected by those skilled in the art according to actual needs. More preferably, a duty cycle of the plurality of photonic crystal microstructures 108 is 1:1. The duty cycle is a ratio of the total area of the cross sections of the plurality of photonic crystal microstructures 108 parallel to the plane of the transmission enhanced layer 107 to the total real of the intervals. It is to be noted that, the duty cycle of the plurality of photonic crystal microstructures 108 being 1:1 is merely a preferred embodiment, and the duty cycle of other value shall fall into the protection scope of the present invention. In practical applications, the shapes of the plurality of photonic crystal microstructures 108 of the transmission enhanced layer 107 may differ from one another, and the arrangement modes of the plurality of photonic crystal microstructures 108 may also differ from one another. The same shape and corresponding regular arrangement of the plurality of photonic crystal microstructures 108 may improve the probability of refraction of light while transmitting through the transmission enhanced layer 107, thereby forming light in more different directions.

Step 52: forming an anode layer, a functional layer and a cathode layer above the substrate with the transmission enhanced layer formed thereon, so that the functional layer is provided between the anode layer and the cathode layer.

Referring to FIG. 2, an anode layer 103, a functional layer 104 and a cathode layer 105 are successively provided on the substrate 101. In this embodiment, the light emitting device further includes a planarization layer 102. The planarization layer 102 is provided between the transmission enhanced layer 107 and the anode layer 103, and a part of the planarization layer 102 is located within the intervals between the plurality of photonic crystal microstructures 108. Preferably, the planarization material 102 is made of RGB color filter material or PI material. Referring to FIG. 4, the interface between the transmission enhanced layer 107 and the planarization layer 102 forms an irregular interface. Light 106 is refracted on the interface to form light in different directions, so that the incident angle of light incident to the substrate 101 is reduced. Therefore, the total reflection generated when light transmits through the interface between the substrate and the air is reduced, the luminous efficiency is improved, and the power loss is reduced.

In this embodiment, a total reflection metal layer may be provided above the cathode layer 105. The total reflection metal layer is used for totally reflecting light 106 to the transmission enhanced layer 107, and then the light is refracted by the transmission enhanced layer 107 to form light at different angles, so that the luminous efficiency is improved, and the power loss is reduced.

In the method for manufacturing a light emitting device provided by the present invention, the light emitting device includes a substrate; an anode layer, a functional layer and a cathode layer are provided above the substrate, and the functional layer is provided between the anode layer and the cathode layer; a transmission enhanced layer is further provided on the substrate; the transmission enhanced layer includes a plurality of photonic crystal microstructures, so that light is refracted while transmitting through the transmission enhanced layer, so as to form light in different directions and thus to reduce an incident angle of light incident to the substrate. Therefore, the total reflection generated when light transmits through an interface between the substrate and the air is reduced, thereby improving luminous efficiency and reducing power loss.

It should be understood that the foregoing implementations are merely exemplary implementations used for describing the principle of the present invention, but the present invention is not limited thereto. A person of ordinary skill in the art may make various modifications and improvements without departing from the spirit and essence of the present invention, and those modifications and improvements shall fall into the protection scope of the present invention.

1. A light emitting device, comprising a substrate, wherein an anode layer, a functional layer and a cathode layer are provided above the substrate, the functional layer being provided between the anode layer and the cathode layer, a transmission enhanced layer being further provided on the substrate, and the transmission enhanced layer comprising a plurality of photonic crystal microstructures.

2. The light emitting device according to claim 1, wherein the plurality of photonic crystal microstructures are arranged at intervals.

3. The light emitting device according to claim 2, wherein the plurality of photonic crystal microstructures are arranged at equal intervals.

4. The light emitting device according to claim 1, wherein the transmission enhanced layer is provided under the anode layer.

5. The light emitting device according to claim 3, wherein the height of each of the photonic crystal microstructures is 0.4 μm.

6. The light emitting device according to claim 3, wherein the interval between every two adjacent photonic crystal microstructures of the plurality of photonic crystal microstructures is 0.6 μm.

7. The light emitting device according to claim 3, wherein a cross section of each of the photonic crystal microstructures parallel to a plane of the transmission enhanced layer is a regular polygon.

8. The light emitting device according to claim 1, wherein the transmission enhanced layer is made of silicon nitride or silicon oxide.

9. The light emitting device according to claim 2, further comprising a planarization layer, wherein the planarization layer is provided between the transmission enhanced layer and the anode layer, and a part of the planarization layer is located within the intervals between the plurality of photonic crystal microstructures.

10. The light emitting device according to claim 1, wherein each of the plurality of photonic crystal microstructures is a protrusion formed on the substrate.

11. A display device, comprising a light emitting device, wherein the light emitting device comprises a substrate, an anode layer, a functional layer and a cathode layer being provided above the substrate, the functional layer being provided between the anode layer and the cathode layer, a transmission enhanced layer being further provided on the substrate, the transmission enhanced layer comprising a plurality of photonic crystal microstructures.

12. The display device according to claim 11, wherein the plurality of photonic crystal microstructures are arranged at intervals.

13. The display device according to claim 12, wherein the plurality of photonic crystal microstructures are arranged at equal intervals.

14. The display device according to claim 11, wherein the transmission enhanced layer is provided under the anode layer.

15. The display device according to claim 13, wherein the height of each of the photonic crystal microstructures is 0.4 μm.

16. The display device according to claim 13, wherein the interval between every two adjacent photonic crystal microstructures of the plurality of photonic crystal microstructures is 0.6 μm.

17. The display device according to claim 13, wherein a cross section of each of the photonic crystal microstructures parallel to a plane of the transmission enhanced layer is a regular polygon.

18. The display device according to claim 11, wherein the transmission enhanced layer is made of silicon nitride or silicon oxide.

19. The display device according to claim 12, wherein the light emitting device further comprises a planarization layer, the planarization layer being provided between the transmission enhanced layer and the anode layer, a part of the planarization layer being located within the intervals between the plurality of photonic crystal microstructures.

20. A method for manufacturing a light emitting device, comprising:
forming a transmission enhanced layer on a substrate, so that the transmission enhanced layer comprises a plurality of photonic crystal microstructures; and
forming an anode layer, a functional layer and a cathode layer above the substrate with the transmission enhanced layer formed thereon, so that the functional layer is provided between the anode layer and the cathode layer.
